(19) United States
(12) Patent Application Publication
(10) Pub. No.: US 2018/0229454 A1
(43) Pub. Date: Aug. 16, 2018

(54) METHOD AND SYSTEM FOR FORMING A MASKING LAYER

(71) Applicant: Agency for Science, Technology and Research, Singapore (SG)

(72) Inventor: Yau Yen Ooi, Singapore (SG)

(21) Appl. No.: 15/750,050

(22) PCT Filed: Jun. 27, 2016
(86) PCT No.: PCT/SG2016/050294

§ 371 Date: Feb. 2, 2018

(30) Foreign Application Priority Data
Aug. 31, 2015 (SG) 10201506899W

(51) Int. Cl. B29C 70/74; B81C 1/00; B29C 33/38; B29C 35/08

(52) U.S. Cl. CPC B29C 70/745; B81C 1/00349; B29C 2035/0827; B29C 35/0888; B29C 33/38

(57) ABSTRACT

In various embodiments, a method of forming a masking layer on at least a portion of an object. The method may include providing a plurality of mould pieces. The method may include forming an assembled mould using the plurality of the mould pieces. The assembled mould may include one or more inner surfaces to define a cavity for holding the portion of the object. The method may include providing a masking fluid in said cavity. The method may include providing electromagnetic waves to cure the masking fluid to form the masking layer on the portion of the object.

### CROSS-REFERENCE TO RELATED APPLICATION

This application claims the benefit of priority of Singapore application No. 10201506899W filed on Aug. 31, 2015, the contents of it being hereby incorporated by reference in its entirety for all purposes.

### TECHNICAL FIELD

Various aspects of this disclosure relate to a method of forming a masking layer on at least a portion of an object, and to a system for forming a masking layer on at least a portion of an object.

### BACKGROUND

Gas turbine engine components such as compressors and turbine blades often require coatings such as aluminides for environmental protection or as bond coats. Only certain portions of the blade, such as the curved airfoils region, that is exposed to hot gases require such protection. The remainder portions of the blade, such as the dovetail or root, may not require such protection. In fact, it may be undesirable to have coating on the remaining portions of the blade.

In order to achieve the desired properties in various portions of the blade so as to maximize the life of the component, it has been necessary to devise methods and systems to properly coat the airfoil portion without affecting the dovetail or root portion.

### SUMMARY

In various embodiments, a method of forming a masking layer on at least a portion of an object. The method may include providing a plurality of mould pieces. The method may include forming an assembled mould using the plurality of mould pieces. The assembled mould may include one or more inner surfaces to define a cavity for holding the portion of the object. The method may include providing a masking fluid in said cavity. The method may include providing electromagnetic waves to cure the masking fluid to form the masking layer on the portion of the object.

In various embodiments, a system for forming a masking layer on at least a portion of an object may be provided. The system may include a plurality of mould pieces. The plurality of mould pieces may be configured to form an assembled mould. The assembled mould may include one or more inner surfaces to define a cavity for holding the portion of the object. The system may further include a dispenser configured to dispense a masking fluid in said cavity. The system may additionally include one or more electromagnetic wave sources configured to provide electromagnetic waves to cure the masking fluid to form the masking layer on the portion of the object.

### BRIEF DESCRIPTION OF THE DRAWINGS

The invention will be better understood with reference to the detailed description when considered in conjunction with the non-limiting examples and the accompanying drawings, in which:

FIG. 1 is a schematic illustrating a method of forming a masking layer according to various embodiments.

FIG. 2 is a schematic illustrating a system for forming a masking layer on at least a portion of an object according to various embodiments.

FIG. 3 is a schematic illustrating a system for forming a masking layer on at least a portion of an object according to various embodiments.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, and logical changes may be made without departing from the scope of the invention. The various embodiments are not necessarily mutually exclusive, as some embodiments can be combined with one or more other embodiments to form new embodiments.

One of the methods of coating only the desired portions of the blade is to mask the portions that do not require coating with a sacrificial material, that is to say, the dovetail or root, before inserting the blade into a coating apparatus. The sacrificial material is removed after the coating process. Masking is generally considered to be useful but it is a time-consuming and labor intensive process.

Various embodiments seek to address or mitigate the abovementioned issues. Various embodiments seek to reduce the time in forming a masking layer. Various embodiments seek to reduce manpower for masking an object.

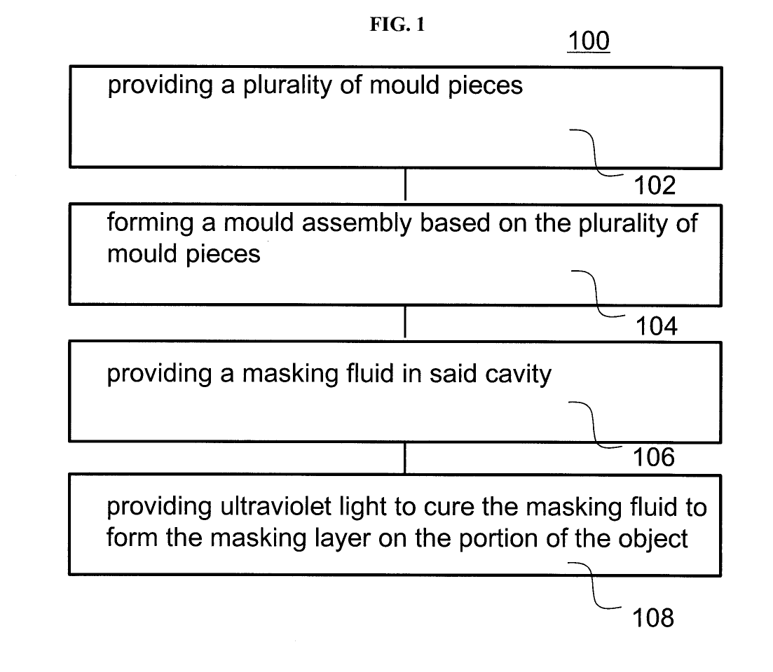

In various embodiments, a method of forming a masking layer on at least a portion of an object. FIG. 1 is a schematic 100 illustrating a method of forming a masking layer according to various embodiments. The method may include, in 102, providing a plurality of mould pieces. The method may include, in 104, forming an assembled mould using or based on the plurality of mould pieces. The assembled mould may include one or more inner surfaces to define a cavity for holding the portion of the object. The method may include, in 106, providing a masking fluid in said cavity. The method may include, in 108, providing electromagnetic waves to cure the masking fluid to form the masking layer on the portion of the object.

In other words, separate pieces of a mould may be moved relative towards one another or brought together to enclose or encapsulate a portion of an object. The object may be positioned or contained within a cavity of the mould. The cavity may be formed by bringing separate pieces of the mould together. The masking fluid may be introduced into the cavity, i.e. between the object portion and the inner surface(s) of the mould. Electromagnetic radiation may be used to cure the masking fluid, which then hardens to form a masking layer on the portion of the object.

In various embodiments, the object may be an aircraft engine component such as a compressor or a turbine blade. For a turbine blade, the portion in which a masking layer is applied on may be the dovetail region. The masking layer may help protect the dovetail region from effects of subsequent processes such as sandblasting and/or painting. The masking layer may protect the surface or portion in which the masking layer is on from damage.

The object may not be limited to an aircraft engine component. In various other embodiments, the object may be any suitable object of a regular shape or of an irregular shape. Various embodiments may be particularly suitable for coating objects or portions of objects of complex or irregular shapes. In various embodiments, the object may be, for instance, a vehicular structural component, a frame or casing of an engine, a machined aircraft or automobile component such as a piston, a gear, a driveshaft etc. The object may be alternatively referred to as a workpiece.

In various embodiments, the electromagnetic waves may have a suitable value or range of values selected from a range of about 10 nm to about 700 nm, or about 10 nm to about 380 nm. In various embodiments, the electromagnetic waves may be ultraviolet light. The masking fluid may be configured to be cured by ultraviolet light. In various embodiments, the electromagnetic waves may be visible light. The masking fluid may be configured to be cured by visible light and/or or heat.

The masking fluid may be any suitable fluid or liquid that is configured to be cured by the electromagnetic waves. The masking fluid may be referred to as liquid maskant or liquid masking fluid. The masking fluid used may be dependent on the electromagnetic waves used as well as the material of the object. The masking fluid may be or may include a photopolymer. In various embodiments, the masking fluid may be a composition including an acrylate such as epoxy acrylate, polyester acrylate or polyurethane acrylate. The composition may also include photoinitators, additives and/or modifiers. The acrylate may provide the basic property of the masking fluid. The photoinitator may induce the polymerization (curing) process when the composition is exposed to the electromagnetic waves, e.g. ultraviolet light. Additives and modifiers may be used to enhance coating properties such as wetting, surface leveling, flow rate, colour, durability, ease of peeling or removal etc.

During the curing process, polymeric chains in the masking fluid, upon exposure to electromagnetic waves such as ultraviolet light and/or visible light, cross-link with one another to form a network polymer, which forms the solid masking layer. In various embodiments, the masking fluid may include a photoinitiator. Photoinitators are compounds that may, upon radiation of electromagnetic waves, decompose into reactive species that activate polymerization of specific functional groups on the polymeric chains, thus initiating or accelerating the curing process.

The plurality of mould pieces may include or consist of a first mould piece and a second mould piece. One or both the first mould piece and the second mould piece may be moved towards each other to form the assembled mould. The first mould piece and the second mould piece may be moved relative towards each other, i.e. the first mould piece may be moved towards the second mould piece or the second mould piece may be moved towards the first piece or both the first mould piece and the second mould piece may be moved towards each other. The first mould piece and the second mould piece may be brought together. In various embodiments, the one or both the first mould piece and the second mould piece are moved relative towards each other until the first mould piece and the second mould piece are in contact with each other to form the assembled mould.

The portion of the object may be positioned or arranged between the first mould piece and the second mould piece before the first mould piece and the second mould piece are brought together. The first mould piece may include a portion that forms a first part of the inner surface(s) defining the cavity, and the second mould piece may include a second portion that forms a second part of the inner surface(s) defining the cavity. The portion that forms the first part of the inner surface(s) and the portion that forms the second part of the inner surface(s) may face the portion of the object (and each other) when the first mould piece and the second mould piece are moved relative towards each other. When the first mould piece and the second mould piece are brought together, the portion of the object may be within the cavity defined by the inner surface(s).

In various other embodiments, the number of mould pieces may be more than two. The portion of the object may be positioned or arranged between the plurality of mould pieces when they are moved relative towards one another or brought together. Each mould piece of the plurality of mould pieces may include a portion that forms a part of the inner surface(s) defining the cavity. The portions may face the portion of the object when the plurality of mould pieces are moved relative towards one another or brought together. When the plurality of mould pieces is brought together, the portion of the object may be within the cavity defined by the inner surface(s).

In various embodiments, the plurality of mould pieces may initially be separate from one another. The plurality of mould pieces may be moved relative towards one another or brought together, after the portion of the object is provided or positioned between the plurality of mould pieces, so that the portion of the object is subsequently enclosed within the cavity of the mould formed or assembled by the plurality of mould pieces. When the plurality of mould pieces is brought together, the mould pieces are closer to one another other compared to when the plurality of mould pieces are separate from one another.

In various embodiments, the plurality of mould pieces may initially be connected to one another but may be in a first position or orientation so that a mould assembly (including the plurality of mould pieces) is in an open state for insertion of the object portion. After the insertion of the object portion, the plurality of mould pieces may be moved relative towards each other, i.e. to a second position or orientation so that the mould assembly is in a closed state. In other words, moving the plurality of mould pieces relative towards one another (or bringing the plurality of mould pieces together) may refer to or may include operating the mould assembly to switch from an open state to a closed state. When the mould assembly is in the closed state, the object portion is within a cavity of the mould assembly. The cavity may be formed by the plurality of mould pieces when the mould assembly is in the closed state. The plurality of mould pieces may be in contact with one another (or with neighbouring mould pieces) when the mould assembly is in the closed state.

After the masking layer is formed, the plurality of mould pieces may be moved away relative to one other. The method may further include moving one or more of the plurality of mould pieces away relative to one another after the masking layer is formed to extract or remove the object from the mould. For instance, the first mould piece and/or the second mould piece may be moved so they are further away relative to each other. In various embodiments, the method may include disassembling the assembled mould.

Moving one or more of the plurality of mould pieces away relative to one another may refer to or may include operating the mould assembly to switch from a closed state to an open state.

The mould or mould pieces may be configured to allow at least a portion of the electromagnetic waves to pass through. In various embodiments, at least a part of the mould or a mould piece may be configured to allow a portion of the electromagnetic waves to pass through. In various embodiments, the mould/mould piece or part of the mould/mould piece may be transparent or translucent. The mould or mould pieces may include a suitable material such as a non-stick material such as polytetrafluoroethylene (PTFE) or Teflon. Other materials such as glass or quartz may not be suitable materials for the mould/mould piece, as these materials may form a tight bond with the masking fluid. It may not be possible to open the mould if the mould/mould piece is made of materials such as glass or quartz.

In various embodiments, the method may be an automated process. In various embodiments, the moving of one or more of the mould pieces towards or away relative to one another may be carried out by one or more actuators. The one or more actuators may be controlled by a processing system, which may alternatively be referred to as a processor system. The processing system may be configured to control the one or more actuators to move the one or more of the plurality of mould pieces towards one another to form the assembled mould. The processing system may further be configured to control a dispenser to provide the masking fluid to the cavity after one or more of the plurality of mould pieces is moved relatively towards one another to form the assembled mould with the object portion within the cavity. The processing system may be configured to control an amount of the masking fluid to be provided to the cavity. The processing system may be also configured to control the one or more actuators to move the one or more of the plurality of mould pieces away from one another after the masking layer is formed.

The processing system may additionally be configured to control one or more electromagnetic waves sources to cure the masking fluid to form the masking layer. The processing system may be configured to control the one or more actuators to move the one or more of the plurality of mould pieces away from one another after a (first) predetermined period of time from the time in which the masking fluid is provided to the cavity, or after a (second) predetermined period of time from the time in which the one or more electromagnetic wave sources are activated to provide the electromagnetic waves for curing the masking fluid.

The one or more electromagnetic wave sources may be configured to provide electromagnetic waves for a predetermined duration. The predetermined duration may be a suitable time period selected from a range from about 1 second to about 2 minutes, or from about 5 seconds to about 1 minute, or from about 10 seconds to about 30 seconds. The predetermined duration may be sufficient for the masking fluid to be cured to form the masking layer. In various embodiments, the processing system may be configured to control the one or more electromagnetic wave sources to provide electromagnetic waves for the predetermined duration.

In various embodiments, the system may include a handling mechanism such as a robotic arm configured to provide or position the object portion between the mould pieces before the mould pieces are assembled. The handling mechanism may be further configured to remove or extract or move the object after the masking layer is formed. The handling system may be controlled by the processing system.

Various embodiments may not require manual input or may only require reduced or minimal manual input.

It may also be envisioned that the system may include a sensor configured to detect the curing of the masking fluid or to detect the formation of the masking layer. The sensor may be connected to the processing system. Upon detecting that the masking fluid has cured to form the masking layer, the sensor may send a signal to the processing system. The processing system may provide an indication (e.g. indicator light) to indicate to an user that the curing process is completed or may control the actuator to move the mould pieces away relative to one another.

In various embodiments, the plurality of mould pieces may be configured to be attached or secured to one another to form the assembled mould. For instance, the plurality of mould pieces may have an attachment mechanism configured to allow attachment of the plurality of mould pieces to one another.

The plurality of mould pieces or mould may include a sealing mechanism to prevent or reduce the leakage of the masking fluid when the masking fluid is provided in said cavity.

In various embodiments, the assembled mould may include an inlet channel configured to receive the masking fluid. The assembled mould may be further configured to allow the liquid masking layer to flow into said cavity.

In various embodiments, the inlet channel may be configured to receive the masking fluid, and further configured to allow the masking fluid to flow into said cavity. A surface defining the inlet channel may be coated with an optically opaque coating such as chrome or similar metallic coating such as aluminum, silver or gold coating etc. The optically opaque coating may reduce or prevent electromagnetic waves, e.g. ultraviolet light, from reaching the inlet channel, thus reducing or preventing the masking fluid from curing inside the inlet channel and clogging the inlet channel.

In various alternate embodiments, the method may include inserting a delivery tube through the inlet channel. The method may further include providing the masking fluid to said cavity through the delivery tube. The delivery tube may include a material configured to block electromagnetic waves. The material may be a metal such as aluminum, stainless steel, copper etc. The material may reduce or prevent electromagnetic waves, e.g. ultraviolet light, from reaching the delivery tube, thus reducing or preventing the masking fluid from curing inside the delivery tube and clogging the delivery tube.

In various embodiments, the one or more inner surfaces may be coated with one or more reflective coatings for directing electromagnetic waves towards the portion of the object. The reflective coating may for instance, include aluminum, chrome, silver, gold or polished stainless steel.

The one or more inner surfaces of the assembled mould and the portion of the object may be separated by a gap when the portion of the object is within the cavity. The masking fluid may be provided or introduced to the gap.

In various embodiments, the mould may be configured to correspond to a shape of the portion of the object. The inner surface(s) of the assembled mould and the portion of the object may be complementary in shape. The mould may be configured or may be patterned in such a manner so that the gap formed between the inner surface(s) and the portion of the object is substantially uniform over the surface of the object (with maybe the exception of the portion adjacent to the inlet channel).

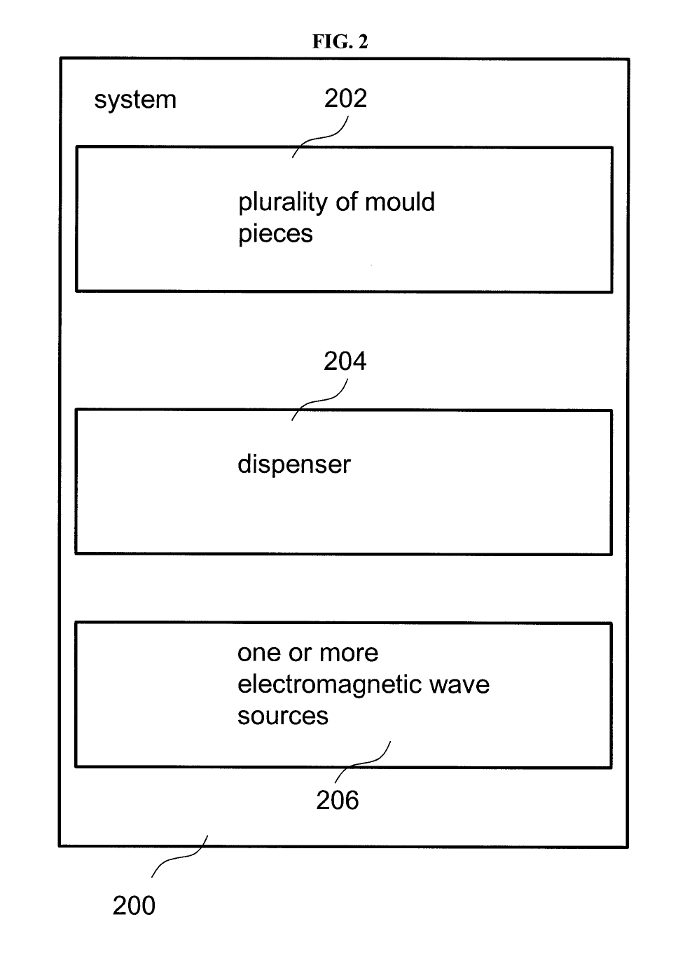

In various embodiments, a system for forming a masking layer on at least a portion of an object may be provided. FIG. 2 is a schematic illustrating a system 200 for forming a masking layer on at least a portion of an object according to various embodiments. The system 200 may include a plurality of mould pieces 202. The plurality of mould pieces 202 may be configured to form an assembled mould. The assembled mould may include one or more inner surfaces to define a cavity for holding the portion of the object. The system 200 may further include a dispenser 204 configured to provide a masking fluid in said cavity. The system 200 may additionally include one or more electromagnetic wave sources 206 configured to provide electromagnetic waves to cure the masking fluid to form the masking layer on the portion of the object.

In other words, the system 200 may include a plurality of mould pieces 202 which may be assembled together to form a mould with a cavity for containing a portion of the object. The system may include a dispenser 204 configured to dispense or introduce a masking fluid into said cavity. Electromagnetic waves are provided by sources 206 to harden the masking fluid so that the masking layer is formed on the portion of the object.

In various embodiments, the one or more electromagnetic wave sources 206 may be configured to provide ultraviolet light. An electromagnetic source 206 configured to provide ultraviolet light may be referred to as an ultraviolet light source.

In various alternate embodiments, the one or more electromagnetic wave sources 206 may be configured to provide visible light. An electromagnetic source 206 configured to provide visible light may be referred to as a visible light source.

In various embodiments, the one or more inner surfaces of the assembled mould and the portion of the object 202 may be separated by a gap when the portion of the object is within the cavity. In various embodiments, the masking fluid may be provided to the gap.

In various embodiments, the plurality of mould pieces 202 may include a first mould piece and a second mould piece. In various other embodiments, the plurality of mould pieces 202 may include more than two mould pieces.

In various embodiments, the dispenser 204 may be or may include a pump, such as a volumetric pump. The pump may be configured to pump or inject a measure or predetermined amount of masking fluid into the cavity.

In various embodiments, the assembled mould or mould or mould pieces may be configured to allow at least a portion of the electromagnetic waves to pass through. The assembled mould or mould or mould pieces may at least partially be permeable to the electromagnetic waves, e.g. ultraviolet light. The assembled mould or mould or mould pieces may include a suitable material that is configured to allow at least a portion of the electromagnetic waves to pass through.

In various embodiments, the assembled mould or mould or the plurality of mould pieces may be transparent or may be translucent. The assembled mould or mould or the plurality of mould pieces may include a suitable material that is transparent or translucent.

In various embodiments, the assembled mould may include an inlet channel configured to receive the masking fluid. The assembled mould may be further configured to allow the liquid masking layer to flow into said cavity. The inlet channel may be coated with an optical coating. The system 200 may include an optically opaque coating coated on a surface defining the inlet channel.

In various embodiments, the system 200 may further include a delivery tube connected to the dispenser 204. The delivery tube may extend through the inlet channel. The delivery tube may be configured to carry the masking fluid from the dispenser 204 to said cavity.

The delivery tube may include a material configured to block electromagnetic waves.

In various embodiments, the one or more inner surfaces may be coated with one or more reflective coatings for directing or reflecting electromagnetic waves towards the portion of the object.

In various embodiments, the system 200 may be an automated system. The system 200 may include one or more actuators to move one or more of the plurality of mould pieces or the mould assembly. The system 200 may further include a processing system connected to the one or more actuators. The processing system may be configured to control the one or more actuators. The processing system may include one or more computers, or one or more processing circuits.

In various embodiments, a “circuit” may be understood as any kind of a logic implementing entity, which may be special purpose circuitry or a processor executing software stored in a memory, firmware, or any combination thereof. Thus, in various embodiments, a “circuit” may be a hard-wired logic circuit or a programmable logic circuit such as a programmable processor, e.g. a microprocessor (e.g. a Complex Instruction Set Computer (CISC) processor or a Reduced Instruction Set Computer (RISC) processor). A “circuit” may also be a processor executing software, e.g. any kind of computer program, e.g. a computer program using a virtual machine code such as e.g. Java. Any other kind of implementation of the respective functions which will be described in more detail herein may also be understood as a “circuit” in accordance with various alternative embodiments.

In various embodiments, the processing system may be connected to the one or more electromagnetic sources 206. The processing system may be configured to control the one or more electromagnetic sources 206.

In various embodiments, the processing system may be connected to the dispenser. The processing system may be configured to control the dispenser 204. The processing system may be configured to control the dispenser 204.

In various embodiments, the system 200 may include a handling mechanism, e.g. for moving or manipulating the object or object portion. In various embodiments, the processing system may be connected to the handling mechanism. The processing system may be configured to control the handling mechanism.

In various embodiments, the system 200 may include a sensor for detecting the curing of the masking fluid. The processing system may be connected to the sensor. The processing system may be configured to control the sensor.

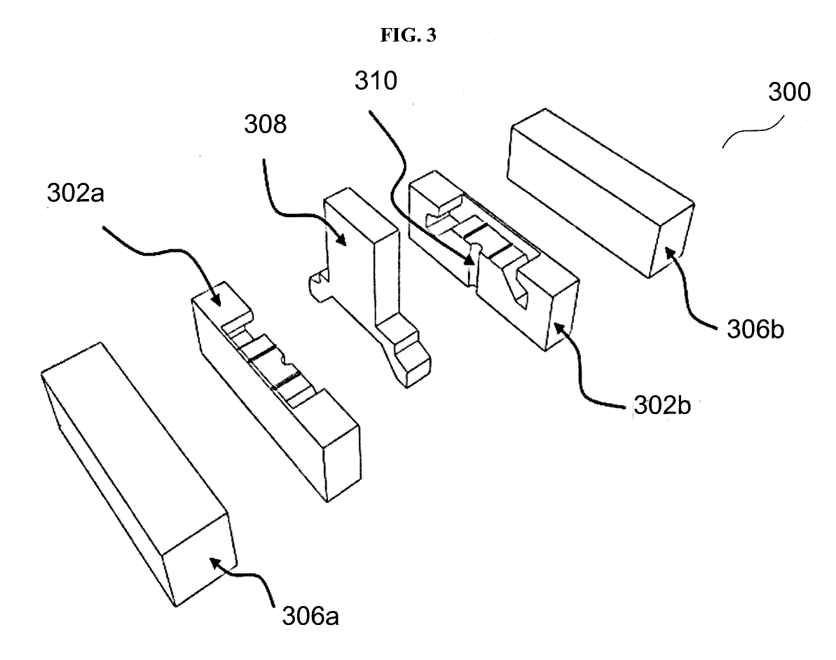

FIG. 3 is a schematic illustrating a system 300 for forming a masking layer on at least a portion of an object 308 according to various embodiments. The object 308 may include a portion to he masked and a further portion not to be masked. The object 308 may have an irregular or complex shape.

The system 300 may include a plurality of mould pieces 302a, 302b. As shown in FIG. 3 the system may include a first mould piece 302a and a second mould piece 302b. A mould piece may alternatively be referred to as a movable mould piece. The first mould piece 302a and the second mould piece 302b may be brought together or assembled to form an assembled mould enclosing the portion of the object 308. The assembled mould may include one or more inner surfaces to define a cavity for holding the portion of the object 308.

The system 300 may also include a dispenser, such as a volumetric pump or volumetric pump device (not shown in FIG. 3). The dispenser may be used to inject a measured amount of masking fluid into the cavity, completely covering the areas to be protected. The masking fluid may be injected into the mould cavity to submerge the areas to be protected. The masking fluid may be injected into a gap between the inner surface(s) defining the cavity and an exterior surface of the object 308. The masking fluid may subsequently be cured using ultraviolet (UV) light.

The system 300 may further include ultraviolet light sources 306a, 306b, such as ultraviolet (UV) lamps, which are configured to generate or provide the UV light. The UV lamps 306a, 306b may be configured to emit ultraviolet light of a suitable wavelength, and may be strategically placed around the mould assembly or mould to focus the UV rays into the cavity. The UV lamps 306a, 306b may turn on and off momentarily, usually for a duration of a few seconds, until the masking fluid is fully cured into a hardened state.

The mould pieces 302a, 302b may be made of a material that is permeable to ultraviolet light. For instance, the mould pieces 302a, 302b may be transparent or translucent to allow at least a portion of the UV light to pass through to reach the masking fluid within the cavity.

At least a portion of a surface of the mould (or first mould piece 302a and/or second mould piece 302b) may be coated with a reflective coating to reflect UV light towards the center of the object.

The hole or inlet channel 310 through which masking fluid is injected may be specially treated with an optically opaque coating to block out UV rays. This is to prevent masking fluid from curing inside the inlet channel 310 which may potentially lead to clogging. Alternatively, a delivery tube made of a UV blocking material, such as a suitable metal, may be used as a shield to prevent clogging.

Various embodiments may relate to a method or technique to apply and cure masking fluid over an object, e.g. an object of a complex shape. The method or technique may be used to rapidly and selectively deposit a substantially uniform or even layer of masking fluid over or on an object so as to protect the surface of the object from damage. The masking layer may be peeled off or burnt off (depending on the type of masking fluid used) after the masking layer is no longer required.

During operation, the mould assembly may be open or the plurality of mould pieces 302a and 302b may be separated from each other or one another. The object or workpiece 308 may be inserted between the plurality of mould pieces 302a and 302b.

The mould assembly may then be closed or the plurality of mould pieces 302a, 302b may be moved relative towards each other or one another to form the assembled mould. A small gap may be formed between the surfaces of the object 308 and the assembled mould.

The volumetric pump may inject a measured amount of masking fluid into the small gap, completely covering or filling the area to be protected.

The UV lamps 306a, 306b may turn on for a brief period of time, usually a few seconds, to completely cure the liquid fluid to a hardened state.

The mould assembly may then be opened or retracted or the plurality of mould pieces 302a, 302b may be moved away relative to each other or one another. The portion of the object 308 may then be extracted.

Various embodiments seek to combine moulding technology with liquid masking.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A method of forming a masking layer on at least a portion of an object, the method comprising:
providing a plurality of mould pieces;
forming an assembled mould using the plurality of mould pieces, the assembled mould comprising one or more inner surfaces to define a cavity for holding the portion of the object;
providing a masking fluid in said cavity; and
providing electromagnetic waves to cure the masking fluid to form the masking layer on the portion of the object.

2. The method according to claim 1,
wherein the one or more inner surfaces of the assembled mould and the portion of the object is separated by a gap when the portion of the object is within the cavity; and
wherein the masking fluid is provided to the gap.

3. The method according to claim 1,
wherein the plurality of mould pieces comprises a first mould piece and a second mould piece; and
wherein the assembled mould is formed using the first mould piece and the second mould piece.

4. The method according to claim 1,
wherein the assembled mould is configured to allow at least a portion of the electromagnetic waves to pass through.

5. The method according to claim 1, further comprising:
moving one or more of the plurality of mould pieces away relative to one another after the masking layer is formed for extracting the object.

6. The method according to claim 1,
wherein the assembled mould comprises an inlet channel.

7. The method according to claim 6,
wherein the inlet channel is configured to receive the masking fluid, and further configured to allow the masking fluid to flow into said cavity; and
wherein a surface defining the inlet channel is coated with an optically opaque coating.

8. The method according to claim 6, further comprising:
inserting a delivery tube through the inlet channel; and
providing the masking fluid to said cavity through the delivery tube.

9. The method according to claim 8,
wherein the delivery tube comprises a material configured to block electromagnetic waves.

10. The method according to claim 1,
wherein the one or more inner surfaces is coated with one or more reflective coatings for directing electromagnetic waves towards the portion of the object.

11. A system for forming a masking layer on at least a portion of an object, the system comprising:
a plurality of mould pieces, the plurality of mould pieces configured to form a assembled mould, the assembled mould comprising one or more inner surfaces to define a cavity for holding the portion of the object;
a dispenser configured to provide a masking fluid in said cavity; and
one or more electromagnetic wave sources configured to provide electromagnetic waves to cure the masking fluid to form the masking layer on the portion of the object.

12. The system according to claim 11,
wherein the dispenser is a pump.

13. The system according to claim 11,
wherein the assembled mould is configured to allow at least a portion of the electromagnetic waves to pass through.

14. The system according to claim 11,
wherein the plurality of mould pieces are transparent.

15. The system according to claim 11,
wherein the plurality of mould pieces are translucent.

16. The system according to claim 11,
wherein the assembled mould comprises an inlet channel configured to receive the masking fluid, and further configured to allow the liquid masking layer to flow into said cavity.

17. The system according to claim 16, further comprising:
an optically opaque coating coated on a surface defining the inlet channel.

18. The system according to claim 11, further comprising:
a delivery tube connected to the dispenser; and
wherein the delivery tube is configured to carry the masking fluid from the dispenser to said cavity.

19. The system according to claim 18,
wherein the delivery tube comprises a material configured to block electromagnetic waves.

20. The system according to claim 11,
wherein the one or more inner surfaces is coated with one or more reflective coatings for directing electromagnetic waves towards the portion of the object.
